(19) United States
(12) Patent Application Publication
(10) Pub. No.: US 2026/0323935 A1
(43) Pub. Date: Oct. 15, 2026

(54) SEMICONDUCTOR DEVICE

(71) Applicant: NANYA TECHNOLOGY CORPORATION, New Taipei City (TW)

(72) Inventor: Wei Zhong Li, New Taipei City (TW)

(73) Assignee: NANYA TECHNOLOGY CORPORATION, New Taipei City (TW)

(21) Appl. No.: 19/180,124

(22) Filed: Apr. 15, 2025

(51) Int. Cl. H10B 20/25

(52) U.S. Cl. CPC H10B 20/25

(57) ABSTRACT

The present disclosure provides a semiconductor device including a cell region where unit cells are arranged in an array and a pick-up region adjacent to the cell region. Each unit cell includes a substrate including a first and a second active regions adjacent to each other in a first direction, a first and a second transistor gates and a fuse gate. The first active region includes a first transistor region having a side facing the second active region and a first capacitor region protruding from the side of the first transistor region. The second active region includes a second transistor region having a side facing the first active region and a second capacitor region protruding from the side of the second transistor region. The first capacitor region and the second capacitor region overlap with the second transistor region and the first transistor region in the first direction, respectively.

### BACKGROUND

### Technical Field

The present invention relates to a semiconductor device, and more particularly, to a semiconductor device including an electrically-programmable semiconductor structure.

### Description of Related Art

The semiconductor industry continues to improve the degree of integration of various electronic components such as transistors, resistors, or capacitors by continual reductions in minimum feature size, which allows more components to be integrated into a given area. Integrated circuit (IC) devices are usually made with all internal connections set during the manufacturing process. However, the end users often desire circuits which can be configured or programmed in the field. Such circuits are called programmable circuits and usually contain programmable links. Programmable links are electrical interconnects which are either broken or created at selected electronic nodes by the user to activate or deactivate respective selected electronic nodes after the integrated circuit device has been fabricated and packaged.

An anti-fuse is one type of the programmable links that has been developed for IC devices. The programming mechanism in the anti-fuse creates a short circuit or a relatively low resistance link therein. The combination of the open circuit and the short circuit of anti-fuse represents a digital bit pattern of “1” and “0” signifying data that the user wishes to store in the IC device. However, anti-fuse structures may occupy a large footprint over semiconductor substrates, and a high current density and a high electric field may be needed.

Therefore, as the sizes of the electronic components continue to decrease, there is a continuous need to increase the layout efficiency.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

The invention provides a semiconductor device in which the first capacitor region and the second capacitor region are designed to respectively overlap with the second transistor region and the first transistor region in the first direction, so that the layout efficiency of the semiconductor device can be increased.

An embodiment of the present invention provides a semiconductor device including a cell region in which unit cells are arranged in an array and a pick-up region adjacent to the cell region. Each unit cell includes a substrate including a first active region and a second active region adjacent to each other in a first direction, a first transistor gate, a second transistor gate, and a fuse gate. The first active region includes a first transistor region having a first side facing the second active region and a first capacitor region protruding from the first side of the first transistor region. The second active region includes a second transistor region having a second side facing the first active region and a second capacitor region protruding from the second side of the second transistor region. The first transistor gate extends on the first transistor region along a second direction crossing the first direction. The second transistor gate extends on the second transistor region along the second direction. The fuse gate extends on the first and second capacitor regions along the second direction. The first capacitor region overlaps with the second transistor region in the first direction, and the second capacitor region overlaps with the first transistor region in the first direction.

In some embodiments, the first transistor region has third sides opposite to each other in the second direction, the second transistor region has fourth sides opposite to each other in the second direction, and the third sides and the fourth sides are aligned to each other in the first direction.

In some embodiments, the first capacitor region has a side aligned with one of the third sides, and the second capacitor region has a side aligned with one of the fourth sides.

In some embodiments, another one of the third sides is offset from the first capacitor region by a first distance, and another one of the fourth sides is offset from the second capacitor region by a second distance.

In some embodiments, the first distance is equal to the second distance.

In some embodiments, the first capacitor region and the second capacitor region are overlapped with and spaced apart from each other in the second direction.

In some embodiments, the fuse gate includes a first sidewall and a second sidewall opposite to each other in the first direction, and the first capacitor region comprises a side facing the second side of the second transistor region and being offset from the second sidewall of the fuse gate by a first distance in a top view.

In some embodiments, the second capacitor region includes a side facing the first side of the first transistor region and being offset from the first sidewall of the fuse gate by a second distance in the top view.

In some embodiments, the first distance is equal to the second distance.

In some embodiments, the fuse gate includes a first sidewall and a second sidewall opposite to each other in the first direction, and the first capacitor region includes a side aligned with the second sidewall of the fuse gate in a top view.

In some embodiments, the second capacitor region includes a side aligned with the first sidewall of the fuse gate in the top view.

In some embodiments, the semiconductor device further includes an isolation structure in the substrate. The isolation structure includes a first portion defining the unit cells and second portions defining the first active regions and the second active regions in the unit cells, and the first active region and the second active region in each unit cell are spaced apart from each other by the second portion therebetween.

In some embodiments, wherein each of the second portions of the isolation structure includes a first segment separating the first transistor region from the second capacitor region, a second segment separating the first capacitor region from the second transistor region, and a third segment connecting the first segment to the second segment and separating the first capacitor region from the second capacitor region.

In some embodiments, the first segment and the second segment extend along the second direction, and the third segment extends along the first direction.

In some embodiments, the fuse gate includes portions standing on the second portion of the isolation structure in each unit cell.

In some embodiments, the portions of the fuse gate are disposed on the first segment or the second segment.

In some embodiments, each unit cell includes a first conductive contact disposed on the first active region and electrically connecting to a first transistor including the first transistor gate; and a second conductive contact disposed on the second active region and electrically connecting to a second transistor including the second transistor gate. The fuse gate on the first active region is coupled to the first transistor, and the fuse gate on the second active region is coupled to the second transistor.

In some embodiments, the first conductive contact is electrically connected to a source of the first transistor, and the second conductive contact is electrically connected to a source of the second transistor.

In some embodiments, a drain of the first transistor is coupled to a first capacitor including the fuse gate in the first active region, and a drain of the second transistor is coupled to a second capacitor including the fuse gate in the second active region.

In some embodiments, the semiconductor device further includes a first landing pad disposed in the pick-up region and connecting to the first transistor gate, a second landing pad disposed in the pick-up region and connecting to the second transistor gate, and a third landing pad disposed in the pick-up region and connecting to the fuse gate.

Based on the above, in the aforementioned semiconductor device, the first capacitor region and the second capacitor region are designed to respectively overlap with the second transistor region and the first transistor region in the first direction, so that the layout efficiency of the semiconductor device can be increased.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic top view of a semiconductor device according to an embodiment of the disclosure.

FIG. 2 is a schematic cross-sectional view taken along line A-A’ of FIG. 1 according to an embodiment of the disclosure.

FIG. 3 is a schematic top view of a unit cell of a semiconductor device according to another embodiment of the disclosure.

FIG. 4 is a schematic cross-sectional view taken along line B-B’ of FIG. 3 according to an embodiment of the disclosure.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

It will be understood that when an element is referred to as being "on" or "connected" to another element, it may be directly on or connected to the other element or intervening elements may be present. If an element is referred to as being "directly on" or "directly connected" to another element, there are no intervening elements present. As used herein, "connection" may refer to both physical and/or electrical connections, and "electrical connection" or "coupling" may refer to the presence of other elements between two elements. As used herein, " electrical connection" may refer to the concept including a physical connection (e.g., wired connection) and a physical disconnection (e.g., wireless connection).

As used herein, "about", "approximately" or "substantially" includes the values as mentioned and the average values within the range of acceptable deviations that can be determined by those of ordinary skill in the art. Consider to the specific amount of errors related to the measurements (i.e., the limitations of the measurement system), the meaning of "about" may be, for example, referred to a value within one or more standard deviations of the value, or within ±30%, ±20%, ±10%, ±5%. Furthermore, the "about", "approximate" or "substantially" used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

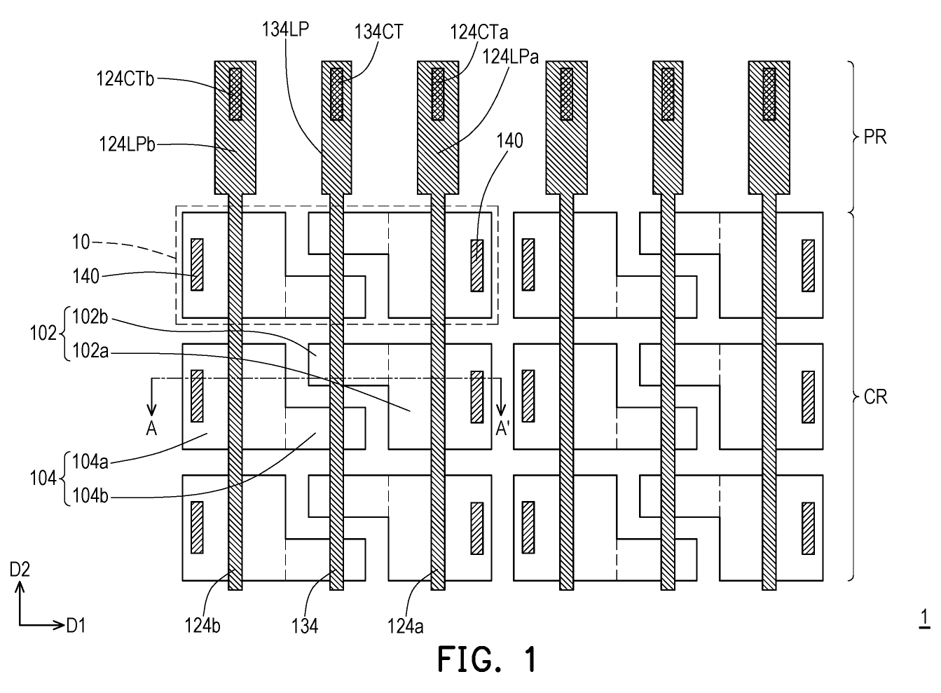

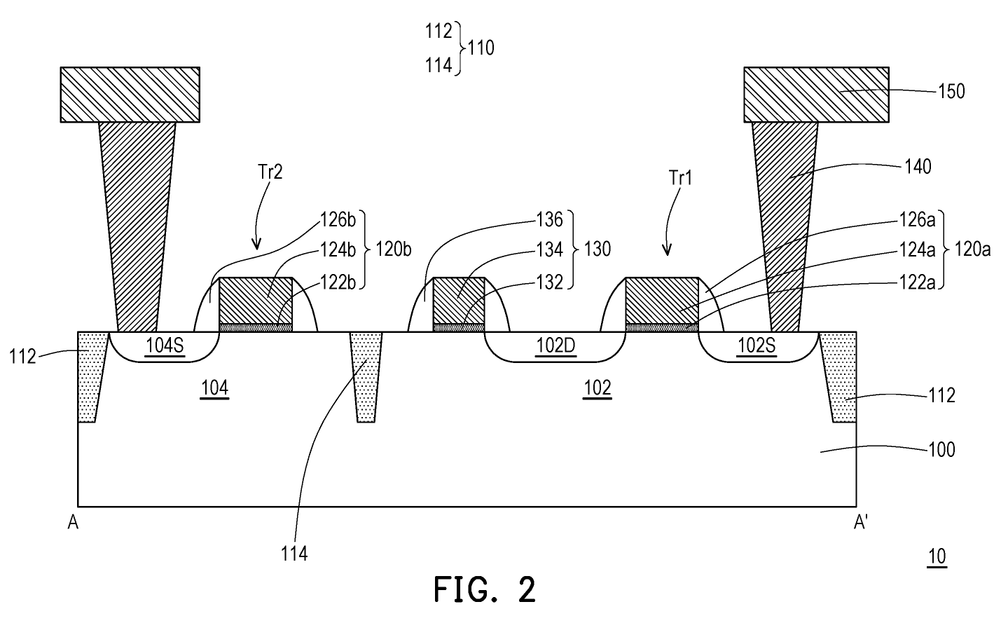

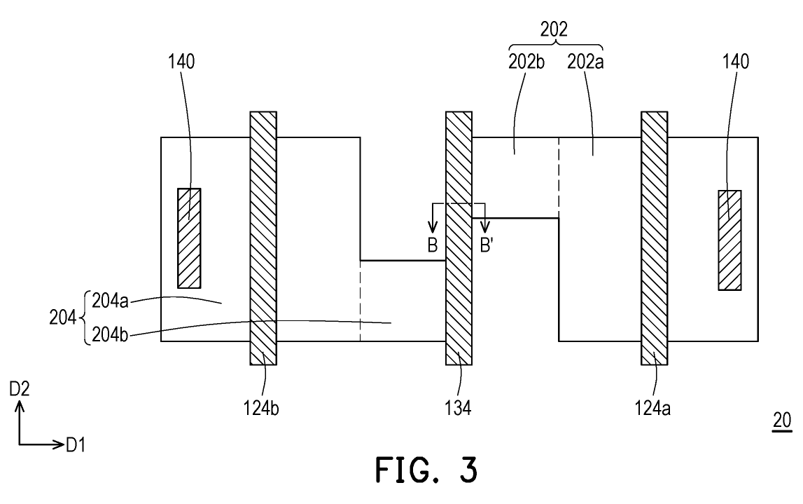

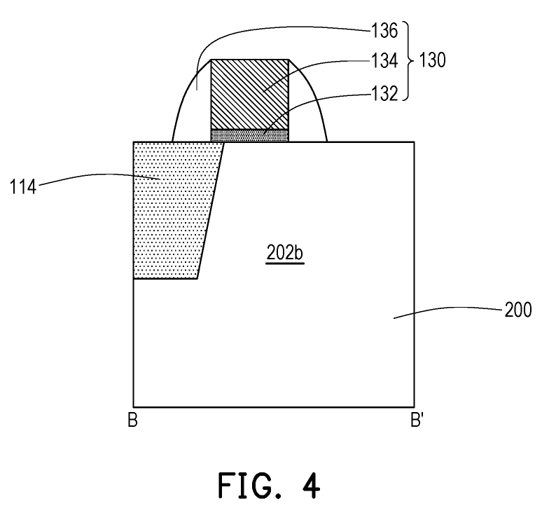

FIG. 1 is a schematic top view of a semiconductor device according to an embodiment of the disclosure. FIG. 2 is a schematic cross-sectional view taken along line A-A’ of FIG. 1 according to an embodiment of the disclosure. FIG. 3 is a schematic top view of a unit cell of a semiconductor device according to another embodiment of the disclosure. FIG. 4 is a schematic cross-sectional view taken along line B-B’ of FIG. 3 according to an embodiment of the disclosure. For convenience of explanation, the substrate 100, the isolation structure 110, the first and second gate dielectric layers 122a and 122b, the first and second gate spacers 126a and 126b, and the wiring layers 150 shown in FIG. 2 are omitted in FIG. 1.

Referring to FIGS. 1 and 2, a semiconductor device 1 according to an embodiment of the disclosure includes a cell region CR in which a plurality of unit cells 10 are arranged in an array and a pick-up region PR adjacent to the cell region. Each of the unit cells 10 includes a substrate 100, a first transistor gate 124a, a second transistor gate 124b, and a fuse gate 134.

The substrate 100 includes a first active region 102 and a second active region 104 adjacent to each other in a first direction D1. In some embodiments, the substrate 100 may include a semiconductor substrate or a semiconductor-on-insulator (SOI) substrate. The semiconductor materials in the semiconductor substrate or in the SOI substrate may include an element semiconductor, an alloy semiconductor, or a compound semiconductor. For example, the element semiconductor may include Si or Ge. The alloy semiconductor may include SiGe, SiGeC, or the like. The compound semiconductor may include SiC, III-V semiconductor materials, or II-VI semiconductor materials. The III-V semiconductor materials may include GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, or InAlPAs. The II-VI semiconductor materials may include CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe. The semiconductor material may be doped with a dopant of a first conductivity type or a dopant of a second conductivity type complementary to the first conductivity type. For example, the first conductivity type may be n-type, whereas the second conductivity type may be p-type.

The first active region 102 includes a first transistor region 102a having a first side facing the second active region 104 and a first capacitor region 102b protruding from the first side of the first transistor region 102a, and the second active region 104 includes a second transistor region 104a having a second side facing the first active region 102 and a second capacitor region 104b protruding from the second side of the second transistor region 104a.

The first transistor gate 124a extends on the first transistor region 102a along a second direction D2 crossing the first direction D1. In some embodiments, the first direction D1 and the second direction D2 are perpendicular to each other. In some embodiments, the first transistor gate 124a may include materials for the gate electrode such as materials for the polysilicon gates or materials for the metal gates. In some embodiments, the first transistor gate 124a may be included in a first gate structure 120a in which a first gate dielectric layer 122a of the first gate structure 120a is disposed between the first transistor gate 124a and the substrate 100, and first gate spacers 126a of the first gate structure 120a are disposed on opposite sides of the stacked structure including the first gate dielectric layer 122a and the first transistor gate 124a. In some embodiments, the first gate dielectric layer 122a may include any suitable material such as silicon oxide. In some embodiments, the first gate spacers 126a may include any suitable material such as silicon oxide, silicon nitride, or silicon oxynitride.

The second transistor gate 124b extends along the second direction D2 on the second transistor region 104a. In some embodiments, the second transistor gate 124b may include materials for the gate electrode such as materials for the polysilicon gates or materials for the metal gates. In some embodiments, the second transistor gate 124a may be included in a second gate structure 120b in which a second gate dielectric layer 122b of the second gate structure 120b is disposed between the second transistor gate 124b and the substrate 100, and second gate spacers 126b of the second gate structure 120b are disposed on opposite sides of the stacked structure including the second gate dielectric layer 122b and the second transistor gate 124b. In some embodiments, the second gate dielectric layer 122b may include any suitable material such as silicon oxide. In some embodiments, the second gate spacers 126b may include any suitable material such as silicon oxide, silicon nitride, or silicon oxynitride.

The fuse gate 134 extends along the second direction D2 on the first capacitor region 102b and the second capacitor region 104b. In some embodiments, the fuse gate 134 may include materials for the gate electrode such as materials for the polysilicon gates or materials for the metal gates. In some embodiments, the materials for the fuse gate 134 may be the same as the materials for the first transistor gate 124a or the second transistor gate 124b. In some embodiments, the fuse gate 134 may be included in a fuse gate structure 130 in which a fuse gate dielectric layer 132 of the fuse gate structure 130 is disposed between the fuse gate 134 and the substrate 100, and fuse gate spacers 136 of the fuse gate structure 130 are disposed on opposite sides of the stacked structure including the fuse gate dielectric layer 132 and the fuse gate 134. In some embodiments, the fuse gate dielectric layer 132 may include any suitable material such as silicon oxide. In some embodiments, the material of the fuse gate dielectric layer 132 may be the same as the material of the first gate dielectric layer 122a or the second gate dielectric layer 122b. In some embodiments, the fuse gate spacers 126b may include any suitable material such as silicon oxide, silicon nitride, or silicon oxynitride. In some embodiments, the materials of the fuse gate spacers 126b may be the same as the materials of the first gate spacers 126a or the second gate spacers 126b. In some embodiments, the fuse gate 134 extends along the second direction D2 between the first transistor gate 124a and the second transistor gate 124b.

In this embodiment, as shown in FIG. 1, the first capacitor region 102b of the first active region 102 is configured to be overlapped with the second transistor region 104a of the second active region 104 in the first direction D1, and the second capacitor region 104b of the second active region 104 is configured to be overlapped with the first transistor region 102a of the first active region 102 in the first direction D1. As such, the amount of the unit cells 10 arranged in the cell region CR can be increased and thus the layout efficiency of the semiconductor device 1 can be improved.

In some embodiments, the first transistor region 102a may include third sides (e.g., upper and lower sides) opposite to each other in the second direction D2, the second transistor region 104a may include fourth sides (e.g., upper and lower sides) opposite to each other in the second direction D2, and the third sides of the first transistor region 102a and the fourth sides of the second transistor region 104a are aligned to each other in the first direction D1. In some embodiments, the first capacitor region 102b has a side aligned with one of the third sides (e.g., the upper side) of the first transistor region 102a, and the second capacitor region 104b has a side aligned with one of the fourth sides (e.g., the lower side). That is, as shown in FIG. 1, the first active region 102 and the second active region 104 may have contours of L-shape in a top view, and the contours of L-shape of the first active region 102 and the second active region 104 are complementary in shape in the first direction D1. In other words, the first capacitor region 102b and the second capacitor region 104b may be overlapped with and spaced apart from each other in the second direction D2. In some embodiments, another one of the third sides (e.g., the lower side) of the first transistor region 102a is offset from the first capacitor region 102b by a first distance, and another one of the fourth sides (e.g., the upper side) of the second transistor region 104a is offset from the second capacitor region 104b by a second distance. In some embodiments, the first distance may be equal to the second distance.

In some embodiments, as shown in FIG. 1, the fuse gate 134 includes a first sidewall and a second sidewall opposite to each other in the first direction D1, and the first capacitor region 102b may include a side facing the second side of the second transistor region 104a and being offset from the second sidewall of the fuse gate 134 by a first distance in a top view. The second capacitor region 104b may include a side facing the first side of the first transistor region 102a and being offset from the first sidewall of the fuse gate 134 by a second distance in the top view. In some embodiments, the first distance may be equal to the second distance.

In some other embodiments, as shown in FIG. 3, the fuse gate 134 included in each unit cell 20 includes a first sidewall and a second sidewall opposite to each other in the first direction D1, and the first capacitor region 202b of the first active region 202 includes a side aligned with the second sidewall of the fuse gate 134 in a top view. The second capacitor region 204b of the second active region 204 includes a side aligned with the first sidewall of the fuse gate 134 in the top view. As a result, the horizontal areas of the first and second transistor regions 102a and 104a remain the same as the horizontal areas of the first and second transistor regions 202a and 204, whereas the horizontal areas of the first and second capacitor regions 202b and 204b are reduced to be less than the horizontal areas of the first and second capacitor regions 102b and 104b. Therefore, the amount of the unit cells 20 can be increased in the given area, and thereby improving the layout efficiency of the semiconductor device.

In some embodiments, the semiconductor device 1 may include an isolation structure 110 in the substrate 100. The isolation structure 110 may include materials suitable for the isolation structure such as oxides (e.g., silicon oxides). In some embodiments, the isolation structure 110 may include a shallow trench isolation (STI) structure. Referring to FIGS. 1 and 2, the isolation structure 110 may include a first portion 112 defining the plurality of unit cells 10 and second portions 114 defining the first active regions 102 and the second active regions 104 in the plurality of unit cells 10. The first active region 102 and the second active region 104 in each unit cell 10 are spaced apart from each other by the second portion 114 therebetween. For example, each of the second portions 114 of the isolation structure 110 may include a first segment separating the first transistor region 102a from the second capacitor region 104b, a second segment separating the first capacitor region 102b from the second transistor region 104a, and a third segment connecting the first segment to the second segment and separating the first capacitor region 102b from the second capacitor region 104b. The first segment and the second segment of the second portion 114 extend along the second direction D2, and the third segment of the second portion 114 extends along the first direction D1.

In some embodiments, when the first capacitor region 202b of the first active region 202 includes the side aligned with the second sidewall of the fuse gate 134 in the top view, and the second capacitor region 204b of the second active region 204 includes the side aligned with the first sidewall of the fuse gate 134 in the top view (as shown in FIG. 3), there may be an embodiment where the first active regions 202 or the second active region 204 in the substrate 200 have rounding corners. In this embodiment, the fuse gate 130 may include portions standing on the second portion 114 of the isolation structure 110 in each unit cell 20 (as shown in FIG. 4). In some embodiments, the portions of the fuse gate 130 are disposed on the first segment or the second segment of the second portion 114.

In some embodiments, as shown in FIGS. 1 and 2, each unit cell 10 may include a first conductive contact 140 disposed on the first active region 102 and electrically connecting to a first transistor Tr1 including the first transistor gate 124a and a second conductive contact 140 disposed on the second active region 104 and electrically connecting to a second transistor Tr2 including the second transistor gate 124b. In some embodiments, the fuse gate 134 on the first active region 102 may be coupled to the first transistor Tr1, and the fuse gate 134 on the second active region 104 may be coupled to the second transistor Tr2. The first and second conductive contacts 140 may each include conductive materials suitable for the conductive contact, such as metals or metal alloys. The metals and the metal alloys may be, for example, Cu, Al, Ti, Ta, W, Pt, Cr, Mo, or alloys thereof. In some embodiment, the first conductive contact 140 may be electrically connected to a source 102S of the first transistor Tr1, and the second conductive contact 140 may be electrically connected to a source 104S of the second transistor Tr2. In some embodiments, a drain 102D of the first transistor Tr1 may be coupled to a first capacitor including the fuse gate 134 in the first active region 102, and a drain of the second transistor Tr2 is coupled to a second capacitor including the fuse gate 134 in the second active region 104.

In some embodiment, the semiconductor device 1 may include a first landing pad 124LPa disposed in the pick-up region PR and connecting to the first transistor gate 124a, a second landing pad 124LPb disposed in the pick-up region PR and connecting to the second transistor gate 124b, and a third landing pad 134LP disposed in the pick-up region PR and connecting to the fuse gate 134. The first landing pad 124LPa, the second landing pad 124LPb, and the third landing pad 134LP may include any suitable conductive material for the landing pad. In some embodiments, the first landing pad 124LPa may include materials identical to the materials for the first transistor gate 124a. In some embodiments, the second landing pad 124LPb may include materials identical to the materials for the second transistor gate 124b. In some embodiments, the third landing pad 134LP may include materials identical to the materials for the fuse gate 134.

In some embodiment, the semiconductor device 1 may include conductive contacts 124CTa, 124CTb and 134CT disposed on and electrically connected to the first landing pad 124LPa, the second landing pad 124LPb, and the third landing pad 134LP, respectively. The conductive contacts 124CTa, 124CTb and 134CT may each include conductive materials suitable for the conductive contact, such as metals or metal alloys. The metals and the metal alloys may be, for example, Cu, Al, Ti, Ta, W, Pt, Cr, Mo, or alloys thereof.

In summary, in the aforementioned semiconductor device, the first capacitor region of the first active region is designed to be overlapped with the second transistor region of the second active region in the first direction, and the second capacitor region of the second active region is designed to be overlapped with the first transistor region of the first active region in the first direction. As such, the amount of the unit cells arranged in the cell region can be increased and thus the layout efficiency of the semiconductor device can be improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device comprising a cell region in which a plurality of unit cells are arranged in an array and a pick-up region adjacent to the cell region, wherein each unit cell comprises:
a substrate comprising a first active region and a second active region adjacent to each other in a first direction, wherein the first active region comprises a first transistor region having a first side facing the second active region and a first capacitor region protruding from the first side of the first transistor region, the second active region comprises a second transistor region having a second side facing the first active region and a second capacitor region protruding from the second side of the second transistor region;
a first transistor gate extending on the first transistor region along a second direction crossing the first direction;
a second transistor gate extending on the second transistor region along the second direction; and
a fuse gate extending on the first and second capacitor regions along the second direction,
wherein the first capacitor region overlaps with the second transistor region in the first direction, and the second capacitor region overlaps with the first transistor region in the first direction.

2. The semiconductor device of claim 1, wherein the first transistor region has third sides opposite to each other in the second direction, the second transistor region has fourth sides opposite to each other in the second direction, and the third sides and the fourth sides are aligned to each other in the first direction.

3. The semiconductor device of claim 2, wherein the first capacitor region has a side aligned with one of the third sides, and the second capacitor region has a side aligned with one of the fourth sides.

4. The semiconductor device of claim 3, wherein another one of the third sides is offset from the first capacitor region by a first distance, and another one of the fourth sides is offset from the second capacitor region by a second distance.

5. The semiconductor device of claim 4, wherein the first distance is equal to the second distance.

6. The semiconductor device of claim 2, wherein the first capacitor region and the second capacitor region are overlapped with and spaced apart from each other in the second direction.

7. The semiconductor device of claim 1, wherein the fuse gate comprises a first sidewall and a second sidewall opposite to each other in the first direction, and the first capacitor region comprises a side facing the second side of the second transistor region and being offset from the second sidewall of the fuse gate by a first distance in a top view.

8. The semiconductor device of claim 7, wherein the second capacitor region comprises a side facing the first side of the first transistor region and being offset from the first sidewall of the fuse gate by a second distance in the top view.

9. The semiconductor device of claim 8, wherein the first distance is equal to the second distance.

10. The semiconductor device of claim 1, wherein the fuse gate comprises a first sidewall and a second sidewall opposite to each other in the first direction, and the first capacitor region comprises a side aligned with the second sidewall of the fuse gate in a top view.

11. The semiconductor device of claim 10, wherein the second capacitor region comprises a side aligned with the first sidewall of the fuse gate in the top view.

12. The semiconductor device of claim 1, further comprising an isolation structure in the substrate, wherein the isolation structure comprises a first portion defining the plurality of unit cells and second portions defining the first active regions and the second active regions in the plurality of unit cells, and the first active region and the second active region in each unit cell are spaced apart from each other by the second portion therebetween.

13. The semiconductor device of claim 12, wherein each of the second portions of the isolation structure comprises a first segment separating the first transistor region from the second capacitor region, a second segment separating the first capacitor region from the second transistor region, and a third segment connecting the first segment to the second segment and separating the first capacitor region from the second capacitor region.

14. The semiconductor device of claim 13, wherein the first segment and the second segment extend along the second direction, and the third segment extends along the first direction.

15. The semiconductor device of claim 14, wherein the fuse gate comprises portions standing on the second portion of the isolation structure in each unit cell.

16. The semiconductor device of claim 15, wherein the portions of the fuse gate are disposed on the first segment or the second segment.

17. The semiconductor device of claim 1, wherein each unit cell comprises:
a first conductive contact disposed on the first active region and electrically connecting to a first transistor comprising the first transistor gate; and
a second conductive contact disposed on the second active region and electrically connecting to a second transistor comprising the second transistor gate,
wherein the fuse gate on the first active region is coupled to the first transistor, and the fuse gate on the second active region is coupled to the second transistor.

18. The semiconductor device of claim 17, wherein the first conductive contact is electrically connected to a source of the first transistor, and the second conductive contact is electrically connected to a source of the second transistor.

19. The semiconductor device of claim 18, wherein a drain of the first transistor is coupled to a first capacitor comprising the fuse gate in the first active region, and a drain of the second transistor is coupled to a second capacitor comprising the fuse gate in the second active region.

20. The semiconductor device of claim 1, further comprising:
a first landing pad disposed in the pick-up region and connecting to the first transistor gate;
a second landing pad disposed in the pick-up region and connecting to the second transistor gate; and
a third landing pad disposed in the pick-up region and connecting to the fuse gate.
